(19) United States
(12) Patent Application Publication
(10) Pub. No.: US 2025/0012870 A1
(43) Pub. Date: Jan. 9, 2025

(54) POWER SUPPLY DEVICE, DIAGNOSIS DEVICE, AND DIAGNOSIS METHOD

(71) Applicant: MURATA MANUFACTURING CO., LTD., Kyoto (JP)

(72) Inventors: Jusuke SHIMURA, Kyoto (JP); Kinichi ITO, Kyoto (JP)

(21) Appl. No.: 18/895,785

(22) Filed: Sep. 25, 2024

Related U.S. Application Data
(63) Continuation of application No. PCT/JP2023/020503, filed on Jun. 1, 2023.

(30) Foreign Application Priority Data
Jun. 2, 2022 (JP) 2022-090411

(51) Int. Cl. G01R 31/392; G01R 31/3842

(52) U.S. Cl. CPC G01R 31/392; G01R 31/3842

(57) ABSTRACT

A power supply device is provided and includes a secondary battery, an electric circuit, and a measurer. The electric circuit performs charging or discharging of the secondary battery. The measurer measures a voltage and a current of the secondary battery. The power supply device further includes a calculator and a deriver. The calculator performs calculation of multiple degradation parameters of the secondary battery based on measurement values obtained by the measurer. The deriver derives a secondary use destination of the secondary battery based on the multiple degradation parameters obtained by the calculation performed by the calculator and respective degradation rates of the multiple degradation parameters set for each of secondary use destination candidates.

### CROSS REFERENCE TO RELATED APPLICATIONS

The present application is a continuation of PCT patent application no. PCT/JP2023/020503, filed on Jun. 1, 2023, which claims priority to Japanese patent application no. 2022-090411, filed on Jun. 2, 2022, the entire contents of which are incorporated herein by reference.

### BACKGROUND

The present technology relates to a power supply device, a diagnosis device, and a diagnosis method.

With expansion of applications of lithium-ion secondary batteries, exhaustion of natural resources such as lithium or cobalt as a raw material has become an issue. As a method for solving this issue, there is given a method of reusing a lithium-ion secondary battery repeatedly until the end of its lifetime is reached. In order to use the lithium-ion secondary battery efficiently, it is important to appropriately know a degradation state of the battery at a time point of completion of primary use and to subject the lithium-ion secondary battery to secondary use that is suitable for the degradation state.

A method is provided of determining whether a lithium-ion secondary battery is usable for secondary use. Diagnosis of a battery after primary use by such method makes it possible to obtain a capacity ratio of a positive electrode, a capacity ratio of a negative electrode, and a deviated capacity of the battery as degradation parameters. Based on the degradation parameters, it is possible to appropriately determine whether the lithium-ion secondary battery is usable for secondary use.

A control device is configured to change, when a primary use destination and a secondary use destination are different, a setting value to a value suitable for the secondary use destination. Using such control device makes it possible, when a lithium-ion battery is coupled to a secondary use destination, to acquire information related to input and output of electric power between the lithium-ion battery and the new use destination, and to perform a control method that corresponds to the information.

### SUMMARY

The present technology relates to a power supply device, a diagnosis device, and a diagnosis method.

However, a method described in the Background section merely allows for determination of whether secondary use is possible, and does not allow for specifically presenting a suitable secondary use. Accordingly, it is difficult to select an appropriate secondary use destination without a high level of technical knowledge in understanding: meanings of a capacity ratio of a positive electrode, a capacity ratio of a negative electrode, and a deviated capacity of a battery; and a state inside the battery after these parameter values have changed.

Further, when a control device described in the Background section is used, parameters are optimized automatically after a secondary battery is coupled to a secondary use destination. However, there is an issue that it is difficult to obtain a sufficient effect from optimizing the parameters if an appropriate secondary use destination has not been selected from a large number of secondary use destinations in the first place.

It is therefore desirable to provide a power supply device, a diagnosis device, and a diagnosis method each of which makes it possible to appropriately determine a degradation state of a secondary battery at a time point of completion of primary use, and to present a secondary use destination that is higher in improvement of efficiency by optimization.

A power supply device according to an embodiment of the present technology includes a secondary battery, an electric circuit, and a measurer. The electric circuit performs charging or discharging of the secondary battery. The measurer measures a voltage and a current of the secondary battery. The power supply device further includes a calculator and a deriver. The calculator performs calculation of multiple degradation parameters of the secondary battery based on measurement values obtained by the measurer. The deriver derives a secondary use destination of the secondary battery based on the multiple degradation parameters obtained by the calculation performed by the calculator and respective degradation rates of the multiple degradation parameters set for each of secondary use destination candidates.

A diagnosis device according to an embodiment of the present technology includes a calculator and a deriver. The calculator performs calculation of multiple degradation parameters of a secondary battery based on a measurement value of a voltage of the secondary battery and a measurement value of a current of the secondary battery. The deriver derives a secondary use destination of the secondary battery based on the multiple degradation parameters obtained by the calculation performed by the calculator and respective degradation rates of the multiple degradation parameters set for each of secondary use destination candidates.

A diagnosis method according to an embodiment of the present technology includes the following two items:
(A) performing calculation of multiple degradation parameters of a secondary battery based on a measurement value of a voltage of the secondary battery and a measurement value of a current of the secondary battery; and
(B) deriving a secondary use destination of the secondary battery based on the multiple degradation parameters obtained by the calculation and respective degradation rates of the multiple degradation parameters set for each of secondary use destination candidates.

According to the power supply device of an of the present technology, the diagnosis device of an embodiment of the present technology, and the diagnosis method of an embodiment of the present technology, the multiple degradation parameters of the secondary battery are calculated based on the measurement value of the voltage of the secondary battery and the measurement value of the current of the secondary battery. Thereafter, the secondary use destination of the secondary battery is derived based on the multiple degradation parameters obtained by the calculation and the respective degradation rates of the multiple degradation parameters set for each of the secondary use destination candidates. This makes it possible to present the secondary use destination that allows the secondary battery to be used as long as possible, avoiding presentation of the secondary use destination in which only a particular degradation parameter reaches a value of a maximum degradation state early and the secondary battery becomes unavailable. Accordingly, the present technology makes it possible to appropriately determine the degradation state of the secondary battery at a time point of completion of primary use, and further, to present the secondary use destination that is higher in improvement of efficiency by optimization.

Note that effects of the present technology are not necessarily limited to those described herein and may include any of a series of effects including described below in relation to the present technology.

### BRIEF DESCRIPTION OF THE FIGURES

FIG. 1 is a diagram illustrating an exemplary functional block of a power supply device according to an embodiment of the present technology.

FIG. 2 is a diagram illustrating an application example of the power supply device of FIG. 1. Part (A) of FIG. 3 is a diagram illustrating an exemplary distribution of five degradation parameters based on a timing of completion of primary use. Part (B) of FIG. 3 is a diagram illustrating an exemplary distribution of the five degradation parameters based on a timing after completion of secondary use.

FIG. 4 is a diagram illustrating an exemplary relationship between a square root of an operating time and positive electrode capacity degradation.

FIG. 5 is a diagram illustrating a procedure of presenting a secondary use destination in the power supply device of FIG. 1.

FIG. 6 is a diagram illustrating an exemplary functional block of a power supply system including a server device according to an embodiment of the present technology.

FIG. 7 is a diagram illustrating an application example of the power supply system of FIG. 6.

FIG. 8 is a diagram illustrating an exemplary functional block of a charging and discharging device according to an embodiment of the present technology.

FIG. 9 is a diagram illustrating an exemplary functional block of a power supply system including a server device according to an embodiment of the present technology.

### DETAILED DESCRIPTION

The present technology is described below in further detail including with reference to the drawings according to an embodiment.

A configuration of a power supply device 100 according to a first embodiment of the present technology will be described. The power supply device 100 is a stand-alone device that supplies electric power using a secondary battery 110 mounted on the power supply device 100 and that does not have a function of communicating with an external device. The power supply device 100 may be used, for example, as an uninterruptible power supply device. The power supply device 100 may be mounted on a vehicle 1000 such as an electric automobile, for example, as illustrated in FIG. 2. The power supply device 100 may also be mounted on, for example, a forklift, an electric motorcycle, or an electric kickboard.

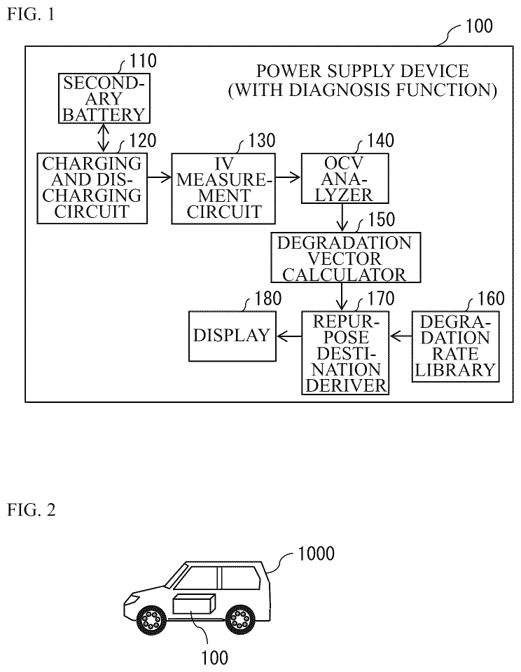

The power supply device 100 has not only a function of supplying electric power but also have a function of presenting a secondary use destination of the secondary battery 110 (the power supply device 100). The “secondary use destination” refers to a new use destination for the used secondary battery 110 (the used power supply device 100). The power supply device 100 includes, for example, the secondary battery 110 as illustrated in FIG. 1.

The secondary battery 110 includes a lithium-ion secondary battery. The lithium-ion secondary battery included in the secondary battery 110 may be a unit cell, a battery block in which multiple unit cells are coupled to each other, or an assembled battery in which a battery block and an accessory are integrally packed. The assembled battery includes multiple lithium-ion secondary batteries coupled to each other in series. The assembled battery may include multiple lithium-ion secondary batteries electrically coupled to each other in parallel.

Examples of the secondary use destination of the secondary battery 110 include the following applications (1) to (4) according to an embodiment.
(1) Application with less occasions of rapid discharging
(2) Application with less occasions of rapid power charging
(3) Application with less time in fully charged state or fully discharged state
(4) Application with less time in low-temperature environment

A decrease in a positive electrode active material is often attributed to application of a large overvoltage to an interface between the positive electrode active material and an electrolytic solution during primary use. Further, a situation in which the large overvoltage is applied to the interface between the positive electrode active material and the electrolytic solution becomes more apparent when lithium ions are inserted into the positive electrode active material than when the lithium ions are extracted from the positive electrode active material. A situation in which the lithium ions are inserted into the positive electrode active material occurs when the lithium-ion secondary battery is discharged. Accordingly, if the lithium-ion secondary battery in which a positive electrode capacity has been decreased in the primary use is rapidly discharged, there is a high possibility that the decrease in the positive electrode capacity will be further accelerated, and there is a high possibility that a lifetime of the lithium-ion secondary battery will be shortened. It is therefore preferable that, when the positive electrode capacity is decreased, the secondary use destination be an application with less occasions of rapid discharging, specific examples of which include an electric automobile, a smartphone, a tablet, and a laptop personal computer.

A decrease in a negative electrode active material is often attributed to application of the large overvoltage to an interface between the negative electrode active material and the electrolytic solution during the primary use. Further, a situation in which the large overvoltage is applied to the interface between the negative electrode active material and the electrolytic solution becomes more apparent when the lithium ions are inserted into the negative electrode active material than when the lithium ions are extracted from the negative electrode active material. A situation in which the lithium ions are inserted into the negative electrode active material occurs when the lithium-ion secondary battery is charged. Accordingly, if the lithium-ion secondary battery in which a negative electrode capacity has been decreased in the primary use is rapidly discharged, there is a high possibility that the decrease in the negative electrode capacity will be further accelerated, and there is a high possibility that the lifetime of the lithium-ion secondary battery will be shortened. It is therefore preferable that, when the negative electrode capacity is decreased, the secondary use destination be an application with less occasions of rapid charging, specific examples of which include an uninterruptible power supply (UPS) device, an electric vacuum cleaner, and a drone.

Degradation in a positive electrode balance or a negative electrode balance of a battery is often attributed to that a positive electrode or a negative electrode is left, for a long time during the primary use, in a state in which a potential of the positive electrode or the negative electrode is close to an electrochemical window. A situation of being left in the state in which the potential is close to the electrochemical window is caused by the lithium-ion secondary battery being left in a fully charged state or a fully discharged state. Accordingly, if the lithium-ion secondary battery in which the positive electrode balance or the negative electrode balance of the battery has been degraded in the primary use is left in the fully charged state or the fully discharged state for a long time, the positive electrode or the negative electrode is caused to be in the state in which the potential is close to the electrochemical window, and there is a high possibility that the degradation in the positive electrode balance or the negative electrode balance will be further accelerated. It is therefore preferable that, when the positive electrode balance or the negative electrode balance is degraded, the secondary use destination be an application with less time in the fully charged state or the fully discharged state, specific examples of which include an energy storage system (ESS) and an electric automobile.

A main factor in an increase in an impedance component of the battery is the number of charging and discharging cycles, and the impedance component increases with an increase in use of the battery. The impedance component that thus increases has a large temperature dependency, and the impedance component increases with a decrease in temperature. In the battery, a substantial capacity available for charging and discharging decreases with an increase in the impedance component. Thus, as for the lithium-ion secondary battery whose impedance component is increased, it is desirable to use the lithium-ion secondary battery in a state in which an impedance value is as low as possible, that is, in an environment within a range from an ambient temperature to a warm temperature. It is therefore preferable that, when the impedance component is increased, the secondary use destination be an application with less time in a low-temperature environment, specific examples of which include an energy storage system (ESS).

Next, degradation parameters to be used for determining the secondary use destination will be described.

In the present embodiment, used as the degradation parameters are positive electrode capacity degradation d_{α}, negative electrode capacity degradation de, positive electrode balance degradation d_{γ}, negative electrode balance degradation do, and impedance degradation de. In order to derive a five-dimensional degradation vector d (Expression (1) below) including these degradation parameters, a method called an open circuit voltage (OCV) analysis is used.

$$d = ( {d}_{α} , {d}_{β} , {d}_{γ} , {d}_{δ} , {d}_{ε} ) \qquad ( 1 )$$

The OCV analysis refers to the following. An open circuit potential (OCP) curve mathematical function φₚ(xₚ) of the positive electrode and an OCP curve mathematical function φₙ(xₙ) of the negative electrode are each individually subjected to expansion and contraction, and parallel translation. Thereafter, a difference between the OCP curve mathematical function φₚ(xₚ) and the OCP curve mathematical function φₙ(xₙ) is determined. Using a mathematical function (Expression (2) below) thereby obtained, charge and discharge curve data (Expression (3) below) obtained by measurement is approximated.

$$\tilde{ν} ( q ) = {ϕ}_{p} [ \frac{q - {S}_{p}}{{Q}_{p}} ] - {ϕ}_{n} [ \frac{q - {S}_{n}}{{Q}_{n}} ] + {R}_{0} j \qquad ( 2 )$$

$$ν ( qi ) ; i = 1 ⋯ n \qquad ( 3 )$$

Here, Sₚ represents positive electrode parallel translation, Qₚ represents a positive electrode capacity, Sₙ represents negative electrode parallel translation, Qₙ represents a negative electrode capacity, and R₀ represents impedance. In the OCV analysis, an electrical characteristic (Sₚ, Qₚ, Sₙ, Qₙ, R₀) of the secondary battery 110 is so determined that a residual sum of squares between Expression (2) and Expression (3) becomes minimum.

The positive electrode capacity degradation d_{α} is a degradation parameter derived from the positive electrode capacity Qₚ obtained by the OCV analysis. When the positive electrode capacity of the secondary battery 110 in an initial state (i.e., the secondary battery 110 that is new and is not degraded) is represented by Q_{p,0}, the positive electrode capacity degradation d_{α} is determined by Expression (4) below. The secondary battery 110 in the initial state corresponds to a specific example of a “reference secondary battery” of the present technology.

$${d}_{α} = 2 - 2 \frac{{Q}_{p , 0} - {0}_{p}}{{Q}_{p , 0}} \qquad ( 4 )$$

In the secondary battery 110 in the initial state, the positive electrode capacity degradation d_{α} is 0. With a decrease in the positive electrode capacity Qₚ, the positive electrode capacity degradation d_{α} increases. When the positive electrode capacity Qₚ decreases to a half of the initial state, the positive electrode capacity degradation d_{α} becomes 1. Such a state is referred to herein as a maximum degradation state.

The maximum degradation state (d_{α}=1) does not correspond to a minimum level of the positive electrode capacity that satisfies a desired specification of a device on which the secondary battery 110 is mounted, but corresponds to a positive electrode capacity below which safety of the secondary battery 110 is regarded as unsecurable at a material level. One reason for this is that the present technology is directed to reduce an environmental burden, i.e., to “use up the secondary battery 110 at the material level without waste”. For the rest of the degradation parameters to be described below, the respective maximum degradation states are defined based on a similar idea.

The negative electrode capacity degradation d_{β} is a degradation parameter derived from the negative electrode capacity Qₙ obtained by the OCV analysis. When the negative electrode capacity of the secondary battery 110 in the initial state is represented by Q_{n,0}, the negative electrode capacity degradation d_{β} is determined by Expression (5) below.

$${d}_{β} = 2 - 2 \frac{{Q}_{n , 0} - {Q}_{n}}{{0}_{n , 0}} \qquad ( 5 )$$

In the secondary battery 110 in the initial state, the negative electrode capacity degradation d_{β} is 0. With a decrease in the negative electrode capacity Qₙ, the negative electrode capacity degradation d_{β} increases. When the negative electrode capacity Qₙ decreases to a half of the initial state, the negative electrode capacity degradation d_{β} becomes 1. Such a state is referred to herein as the maximum degradation state.

The positive electrode balance degradation d_{γ} is a degradation parameter derived from the positive electrode parallel translation Sₚ obtained by the OCV analysis. The positive electrode balance degradation d_{γ} is determined by Expression (6) below.

$${d}_{γ} = 4 \vert \frac{{S}_{p}}{{Q}_{p , 0}} \vert \qquad ( 6 )$$

In the secondary battery 110 in the initial state, the positive electrode balance degradation d_{γ} is 0. With an increase in an absolute value of the positive electrode parallel translation Sₚ, the positive electrode balance degradation d_{γ} increases. When the absolute value of the positive electrode parallel translation Sₚ increases to 25% of the positive electrode capacity Q_{p,0}, the positive electrode balance degradation d_{γ} becomes 1. Such a state is referred to herein as the maximum degradation state.

The negative electrode balance degradation d_{δ} is a degradation parameter derived from the negative electrode parallel translation Sₙ obtained by the OCV analysis. The negative electrode balance degradation do is determined by Expression (7) below.

$${d}_{δ} = 4 \vert \frac{{S}_{n}}{{Q}_{n , 0}} \vert \qquad ( 7 )$$

In the secondary battery 110 in the initial state, the negative electrode balance degradation d_{δ} is 0. With an increase in an absolute value of the negative electrode parallel translation Sₙ, the negative electrode balance degradation d_{δ} increases. When the absolute value of the negative electrode parallel translation Sₙ increases to 25% of the negative electrode capacity Q_{n,0}, the negative electrode balance degradation d_{δ} becomes 1. Such a state is referred to herein as the maximum degradation state.

The impedance degradation de is a degradation parameter derived from the impedance R₀ obtained by the OCV analysis. When the impedance of the secondary battery 110 in the initial state is represented by R_{0,0}, the impedance degradation d_{ε} is determined by Expression (8) below.

$${d}_{ε} = - 2 + 2 \frac{{R}_{0}}{{R}_{0 , 0}} \qquad ( 8 )$$

In the secondary battery 110 in the initial state, the impedance degradation d_{ε} is 0. With an increase in the impedance R₀, the impedance degradation d_{ε} increases. When the impedance R₀ increases to +50% of the initial state, the impedance degradation d_{ε} becomes 1. Such a state is referred to herein as the maximum degradation state.

Next, a description is given of a method of determining the secondary use destination.

In the present technology, it is assumed that the secondary battery 110 is subjected to secondary use and the end of a lifetime of the secondary battery 110 is thereby reached, instead of that the end of the lifetime of the secondary battery 110 is reached by using the secondary battery 110 for only one application. The present technology is directed, in the secondary use, to reduce the environmental burden, i.e., to “use up the secondary battery 110 at the material level without waste”. The secondary use of the secondary battery 110 is presented with an aim of allowing all the degradation parameters to become 1 when the secondary battery 110 is to be discarded.

Part (A) of FIG. 3 illustrates an example of the degradation vector d of the secondary battery 110 based on a timing at which use of the secondary battery 110 in a first application is completed. Part (B) of FIG. 3 illustrates an example of the degradation vector d of the secondary battery based on a timing at which use of the secondary battery 110 in a second application (the secondary use destination) is completed. In part (B) of FIG. 3, the degradation vector d of the secondary battery 110 based on the timing at which the use of the secondary battery 110 in the first application is completed is overlaid on the degradation vector d of the secondary battery based on the timing at which the use of the secondary battery 110 in the second application (the secondary use destination) is completed.

In part (A) of FIG. 3, the negative electrode balance degradation d_{δ} is already 1. As a result, the secondary battery 110 has to be discarded even though the other degradation parameters have not reached 1 yet. As for the secondary battery 110 having such a degradation vector d, materials that are still usable remain, and it may be said that materials are to be wasted.

In contrast, in part (B) of FIG. 3, each of the degradation parameters of the secondary battery 110 based on the timing at which the use of the secondary battery 110 in the second application (the secondary use destination) is completed is substantially 1. One reason for this is that the secondary battery 110 has been used in the secondary use destination in which each of the degradation parameters of the secondary battery 110 becomes substantially 1. In the present technology, the secondary use destination in which materials are prevented from being wasted easily is presented based on the degradation vector d of the secondary battery 110 based on the timing at which the use of the secondary battery 110 in the first application is completed and a degradation rate vector v that is set in advance. The degradation rate vector v is represented by a five-dimensional vector including a positive electrode capacity degradation rate v_{α}, a negative electrode capacity degradation rate v_{β}, a positive electrode balance degradation rate v_{γ}, a negative electrode balance degradation rate v_{δ}, and an impedance degradation rate v_{ε}. The following describes a method of presenting the secondary use destination in detail.

A degradation rate vector v₁ of the secondary battery 110 that has been used in the first application is represented by a five-dimensional vector (Expression (9)) including a positive electrode capacity degradation rate v_{1,α}, a negative electrode capacity degradation rate v_{1,β}, a positive electrode balance degradation rate v_{1,γ}, a negative electrode balance degradation rate v_{1,δ}, and an impedance degradation rate v_{1,ε}.

$${V}_{1} = ( {ν}_{1 , α} , {ν}_{1 , β} , {ν}_{1 , γ} , {ν}_{1 , δ} , {ν}_{1 , ε} ) \qquad ( 9 )$$

A degradation rate vector v₂ of the secondary battery 110 that has been used in the second application (the secondary use destination) is represented by a five-dimensional vector (Expression (10)) including a positive electrode capacity degradation rate v_{2,α}, a negative electrode capacity degradation rate v_{2,β}, a positive electrode balance degradation rate v_{2,γ}, a negative electrode balance degradation rate v_{2,δ}, and an impedance degradation rate v_{2,ε}.

$${V}_{2} = ( {ν}_{2 , α} , {ν}_{2 , β} , {ν}_{2 , γ} , {ν}_{2 , δ} , {ν}_{2 , ε} ) \qquad ( 10 )$$

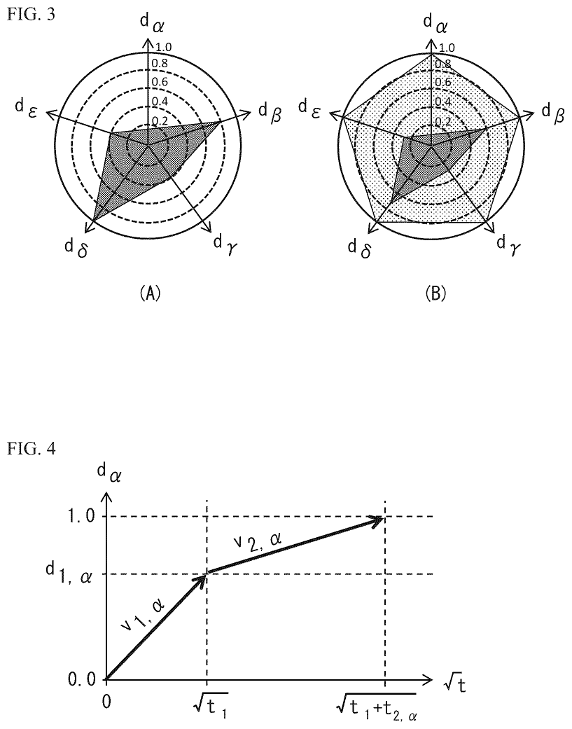

FIG. 4 illustrates an exemplary relationship between a square root of an operating time t of the secondary battery 110 and the positive electrode capacity degradation d_{α}. In FIG. 4, an operating time in the first application is represented by t₁. An operating time in the second application (the secondary use destination) is represented by t_{2,α}. Positive electrode capacity degradation in the first application is represented by d_{1,α}. A positive electrode capacity degradation rate in the first application is represented by v_{1,α}. A positive electrode capacity degradation rate in the second application (the secondary use destination) is represented by v_{2,α}.

The present technology assumes that each of the degradation parameters increases proportionally to the square root of the operating time of the secondary battery 110, as one of the ideas for presenting the secondary use destination by a simple algorithm. The assumption is in accordance with an empirically known “root rule” that holds for degradation of a secondary battery. Because it is assumed that the degradation of the secondary battery is in accordance with the route rule, a degree of degradation of the secondary battery 110 increases linearly with respect to the square root of the operating time t, for example, as illustrated in FIG. 4.

The operating time t_{2,α} in the second application (the secondary use destination) is represented by Expression (11) below.

$${t}_{2 , α} = {( \frac{1 - {d}_{α} {\sqrt{t}}_{1}}{{ν}_{2 , α}} + {\sqrt{t}}_{1} )}^{2} - {t}_{1} \qquad ( 11 )$$

However, as for the degradation of the battery, the positive electrode capacity degradation d_{α} does not proceed alone, but the five degradation parameters proceed independently of each other. When one of the degradation parameter reaches 1 before the rest of the degradation parameters, the use of the battery has to be terminated at that time point. Accordingly, the operating time t_{2,α} itself is not necessarily an actual available time for the second application (the secondary use destination). To find out an actual available time for the second application (the secondary use destination), it is necessary to find out which degradation parameter out of the five degradation parameters reaches 1 the earliest and to find out how long it takes for the degradation parameter that reaches 1 the earliest to reach 1.

First, Expression (11) is expressed as a general expression, as represented by Expression (12).

$${t}_{2 , ξ} = {( \frac{1 - {d}_{ξ} {\sqrt{t}}_{1}}{{ν}_{2 , ξ}} + {\sqrt{t}}_{1} )}^{2} - {t}_{1} \qquad ( 12 )$$

In the second application (the secondary use destination), the actual available time (the operating time t₂) is a minimum value of t_{2,ξ}, and is represented by Expressions (13) and (14) below.

$${t}_{2} = min ( {t}_{2 , α} , {t}_{2 , β} , {t}_{2 , γ} , {t}_{2 , δ} , {t}_{2 , ε} ) = {min}_{ξ ∈ P} {t}_{2 , ξ} \qquad ( 13 )$$

$$P = \{ α , β , γ , δ , ε \} \qquad ( 14 )$$

In order to make all the degradation parameters equal to 1 when the secondary use is completed, the respective operating times t_{2,ξ} of all the degradation parameters may coincide with each other. Accordingly, in the present technology, the secondary use destination is selected based on a degree of coincidence of the operating times t_{2,ξ} of all the degradation parameters. As a specific determination index, there is given Expression (15) or a set of Expressions (16) and (17) below, for example.

$${Argmin}_{{V}_{2}} {( max}_{ξ ∈ P} {t}_{2 , ξ} - {max}_{ξ ∈ P} {t}_{2 , ξ} ) \qquad ( 15 )$$

$${{Argmin}_{V}}_{2} ( \frac{1}{5} {\sum }_{ξ ∈ P}^{5} {( {t}_{2 , ξ} - \overline{{t}_{2}} )}^{2} ) \qquad ( 16 )$$

$$\overline{{t}_{2}} = \frac{1}{5} {\sum }_{ξ ∈ P}^{5} {t}_{2 , ξ} \qquad ( 17 )$$

According to Expression (15), the degradation rate vector v₂ in which a difference between a maximum value and a minimum value of the operating time t_{2,ξ} is minimum is selected. As a result, an application corresponding to the degradation rate vector v₂ selected based on Expression (15) becomes selectable. According to Expression (16), the degradation rate vector v₂ in which a variance of the operating time t_{2,ξ} becomes the minimum is selected. As a result, an application corresponding to the degradation rate vector v₂ selected based on Expression (16) becomes selectable.

Next, the configuration of the power supply device 100 will be described.

As illustrated in FIG. 1, the power supply device 100 includes, for example, the secondary battery 110, a charging and discharging circuit 120, an IV measurement circuit 130, an OCV analyzer 140, a degradation vector calculator 150, a degradation rate library 160, a repurpose destination deriver 170, and a display 180.

The secondary battery 110 includes a lithium-ion secondary battery. The lithium-ion secondary battery included in the secondary battery 110 may be a unit cell, a battery block in which multiple unit cells are coupled to each other, or an assembled battery in which a battery block and an accessory are integrally packed. The assembled battery includes multiple lithium-ion secondary batteries coupled to each other in series. The assembled battery may include multiple lithium-ion secondary batteries electrically coupled to each other in parallel.

The charging and discharging circuit 120 includes a charging circuit that performs charging of the secondary battery 110 and a discharging circuit that performs discharging of the secondary battery 110. The charging circuit includes, for example, an electric generator and a converter, and controls a voltage for charging the secondary battery 110. The IV measurement circuit 130 includes a measurement circuit that measures a current and a voltage of the secondary battery 110. The IV measurement circuit 130 outputs, to the OCV analyzer 140, a current value obtained by the measurement performed by the measurement circuit and a voltage value obtained by the measurement performed by the measurement circuit.

The OCV analyzer 140 performs the OCV analysis based on the measurement values (the current value and the voltage value) obtained by the IV measurement circuit 130. The OCV analyzer 140 approximates, for example, by using Expression (2) described above, the charge and discharge curve data (Expression (3) described above) obtained by the measurement performed by the IV measurement circuit 130. The OCV analyzer 140 thereby derives the electrical characteristic (Sₚ, Qₚ, Sₙ, Qₙ, R₀) of the secondary battery 110.

The degradation vector calculator 150 calculates the five degradation parameters (the degradation vector d) of the secondary battery 110 based on the electrical characteristic (Sₚ, Qₚ, Sₙ, Qₙ, R₀) derived by the OCV analyzer 140 and an electrical characteristic (Q_{p,0}, Q_{n,0}, R_{0,0}) of the secondary battery 110 in the initial state. The degradation vector calculator 150 calculates the degradation vector d, for example, by using Expressions (4) to (8) described above.

The degradation rate library 160 includes a non-volatile memory. The degradation rate library 160 stores the degradation rate vector v set for each of secondary use destination candidates. The degradation rate vector v is, for example, data obtained from the secondary battery 110 prepared as a master. The degradation rate vector v is obtained by solving Expression (18) below, for example, by using the degradation vector d at a time point of the operating time t₁ in the first application.

$$V = \frac{d}{{\sqrt{t}}_{1}} \qquad ( 18 )$$

The repurpose destination deriver 170 derives the secondary use destination of the secondary battery 110 based on the degradation vector d calculated by the degradation vector calculator 150 and the degradation rate vector v read from the degradation rate library 160 and set for each of the secondary use destination candidates. The repurpose destination deriver 170 selects an optimum secondary use destination, for example, by using Expression (15) or (16) described above.

The repurpose destination deriver 170 generates a picture signal including information related to the derived secondary use destination of the secondary battery 110, and outputs the picture signal to the display 180. The display 180 displays the secondary use destination of the secondary battery 110 based on the picture signal inputted from the repurpose destination deriver 170.

Next, an operation of the power supply device 100 will be described.

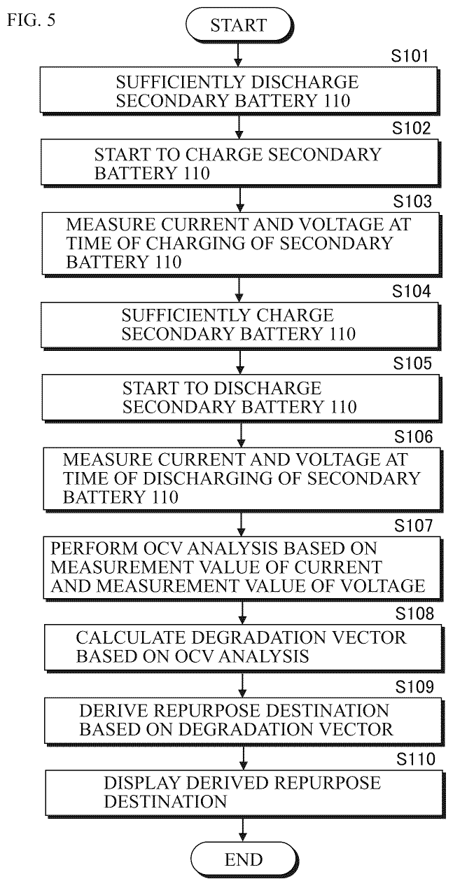

FIG. 5 is a diagram illustrating a procedure of presenting the secondary use destination in the power supply device 100. First, the charging and discharging circuit 120 sufficiently discharges the secondary battery 110 (step S101). Thereafter, the charging and discharging circuit 120 starts to charge the secondary battery 110 (step S102). Thereafter, the IV measurement circuit 130 measures the current and the voltage during charging of the secondary battery 110 (step S103). When the charging and discharging circuit 120 sufficiently charges the secondary battery 110 (step S104), the charging and discharging circuit 120 starts to discharge the secondary battery 110 (step S105). Thereafter, the IV measurement circuit 130 measures the current and the voltage during discharging of the secondary battery 110 (step S106).

Thereafter, the OCV analyzer 140 performs the OCV analysis based on the measurement values at the time of charging and the measurement values at the time of discharging obtained from the IV measurement circuit 130 (step S107). The OCV analyzer 140 generates the charge and discharge curve data, for example, by using the measurement values at the time of charging and the measurement values at the time of discharging obtained from the IV measurement circuit 130, and approximates the generated charge and discharge curve data by using Expression (2) described above. The OCV analyzer 140 thus derives the electrical characteristic (Sₚ, Qₚ, Sₙ, Qₙ, R₀) of the secondary battery 110.

Thereafter, the degradation vector calculator 150 calculates the degradation vector d based on the electrical characteristic (Sₚ, Qₚ, Sₙ, Qₙ, R₀) derived by the OCV analyzer 140 and the electrical characteristic (Q_{p,0}, Q_{n,0}, R_{0,0}) of the secondary battery 110 in the initial state (step S108). The repurpose destination deriver 170 derives the secondary use destination of the secondary battery 110 based on the degradation vector d calculated by the degradation vector calculator 150 and the degradation rate vector v read from the degradation rate library 160 and set for each of the secondary use destination candidates (step S109). The display 180 displays the secondary use destination derived by the repurpose destination deriver 170 (step S110). In this manner, the secondary use destination of the secondary battery 110 is presented.

Next, effects of the power supply device 100 will be described according to an embodiment.

In the present embodiment, the multiple degradation parameters (included in the degradation vector d) of the secondary battery 110 are calculated based on the measurement value of the voltage of the secondary battery 110 and the measurement value of the current of the secondary battery 110. Thereafter, the secondary use destination of the secondary battery 110 is derived based on the multiple degradation parameters (included in the degradation vector d) obtained by the calculation and the respective degradation rates (included in the degradation rate vector v) of the multiple degradation parameters set for each of the secondary use destination candidates. This makes it possible to present the secondary use destination that allows the secondary battery 110 to be used as long as possible, avoiding presentation of the secondary use destination in which only a particular degradation parameter reaches a value of the maximum degradation state early and the secondary battery 110 becomes unavailable. Accordingly, the present embodiment makes it possible to appropriately determine the degradation state of the secondary battery at a time point of completion of primary use, and further, to present the secondary use destination that is higher in improvement of efficiency by optimization.

Further, in the present embodiment, the multiple degradation parameters (included in the degradation vector d) of the secondary battery 110 are calculated based on the electrical characteristic (Sₚ, Qₚ, Sₙ, Qₙ, R₀) of the secondary battery 110 obtained by the OCV analysis and the electrical characteristic (Q_{p,0}, Q_{n,0}, R_{0,0}) of the secondary battery 110 in the initial state. This makes it possible to know the degradation state of the secondary battery 110 in a multifaceted manner, and to effectively select the secondary use destination that is higher in improvement of efficiency by optimization.

Further, in the present embodiment, the secondary use destination is displayed on the display 180. This makes it possible for a user to easily know the secondary use destination.

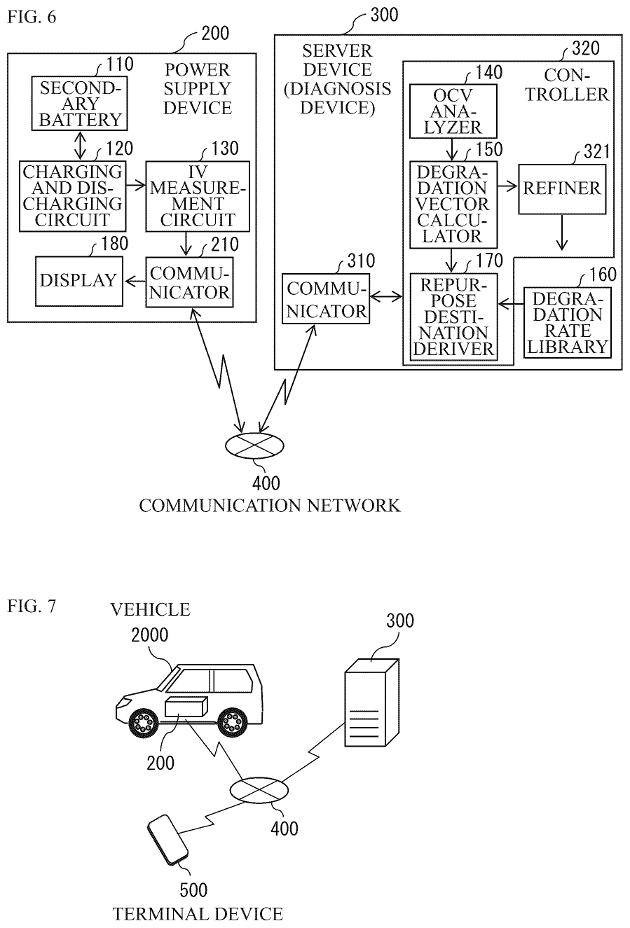

A power supply system including a server device 300 as a diagnosis device according to a second embodiment of the present technology will be described. FIG. 6 illustrates an exemplary functional block of the power supply system. The power supply system includes, for example, a power supply device 200 and the server device 300 as illustrated in FIG. 6. The power supply device 200 and the server device 300 are communicable with each other via a communication network 400. The communication network 400 includes, for example, the Internet, a cloud network, or a network unique to an operator.

The power supply device 200 is a device that supplies electric power using the secondary battery 110 mounted on the power supply device 200, and is a network communication device that has a function of communicating with an external device. The power supply device 200 may be used, for example, as an uninterruptible power supply device. The power supply device 200 may also be used as a battery back-up device, for example. The power supply device 200 may be mounted on a vehicle 2000 such as an electric automobile as illustrated in FIG. 7, for example.

As illustrated in FIG. 6, the power supply device 200 includes, for example, the secondary battery 110, the charging and discharging circuit 120, the IV measurement circuit 130, the display 180, and a communicator 210. The communicator 210 is a communication interface that communicates with the server device 300 via the communication network 400. The IV measurement circuit 130 outputs the measurement values (the current value and the voltage value) obtained by the measurement to the server device 300 via the communicator 210. The display 180 displays the secondary use destination acquired from the server device 300 via the communicator 210.

When the power supply device 200 is to be mounted on the vehicle 2000, for example, the display 180 included in the power supply device 200 may be omitted, and a terminal device 500 having the function of the display 180 may be coupled to the communication network 400. In this case, the terminal device 500 displays the secondary use destination acquired from the server device 300.

As illustrated in FIG. 6, the server device 300 includes, for example, a communicator 310, a controller 320, and the degradation rate library 160. The communicator 310 is a communication interface that communicates with the power supply device 200 via the communication network 400. The controller 320 includes, for example, a central processing unit (CPU). The controller 320 executes, for example, respective functions of the OCV analyzer 140, the degradation vector calculator 150, the repurpose destination deriver 170, and a refiner 321.

The refiner 321 updates the degradation rate vector v stored in the degradation rate library 160 by using the degradation vector d obtained by the degradation vector calculator 150. The refiner 321 may update the degradation rate vector v, for example, by using an exponential moving average as indicated in Expression (19) below. Note that, in Expression (19), a parameter x is determined based on dispersion in values of d/√t1. The parameter x is empirically set to a value that is approximately greater than 0 and less than 0.1.

$${V}_{new} = χ \frac{d}{{\sqrt{t}}_{1}} + ( 1 - χ ) {V}_{old} \qquad ( 19 )$$

In the present embodiment, the server device 300 performs the calculation of the degradation vector d and the degradation rate vector v. In such a case also, it is possible to achieve effects similar to those of the above-described embodiment. Further, such a configuration makes it possible to allow one server device 300 to be shared between multiple power supply devices 200, which allows for reduction in cost of each of the power supply devices 200.

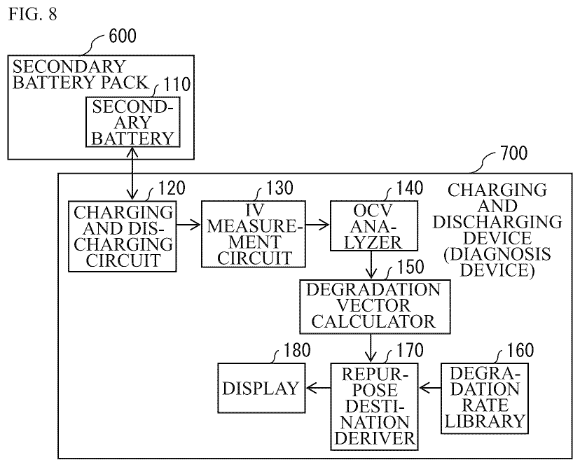

A power supply system including a charging and discharging device 700 having a function as a diagnosis device according to a third embodiment of the present technology will be described. FIG. 8 illustrates an exemplary functional block of the power supply system. The power supply system includes, for example, a secondary battery pack 600 and the charging and discharging device 700 as illustrated in FIG. 8. The secondary battery pack 600 and the charging and discharging device 700 are electrically coupled to each other via an electric coupling circuit.

The secondary battery pack 600 is a portable battery pack, and includes, for example, the secondary battery 110 as illustrated in FIG. 8. Examples of the secondary battery pack 600 include a battery pack for an electric power tool, a battery pack for an electric power-assisted bicycle, and a battery pack for an electric kickboard. The charging and discharging device 700 includes, for example, the charging and discharging circuit 120, the IV measurement circuit 130, the OCV analyzer 140, the degradation vector calculator 150, the degradation rate library 160, and the repurpose destination deriver 170 as illustrated in FIG. 8.

In the present embodiment, the secondary battery 110 is provided inside the secondary battery pack 600. The secondary battery pack 600 is provided separately from the charging and discharging device 700 including the charging and discharging circuit 120, etc. In such a case also, it is possible to achieve effects similar to those of the above-described embodiments. Further, such a configuration makes it possible to also present the secondary use destination for the portable battery pack.

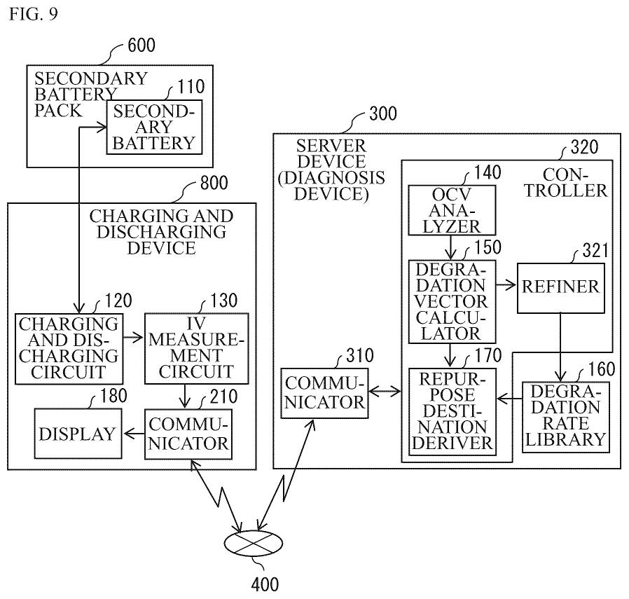

A power supply system including the server device 300 as a diagnosis device according to a fourth embodiment of the present technology will be described. FIG. 9 illustrates an exemplary functional block of the power supply system. The power supply system includes, for example, the secondary battery pack 600, a charging and discharging device 800, and the server device 300, as illustrated in FIG. 9. The charging and discharging device 800 and the server device 300 are communicable with each other via the communication network 400. The charging and discharging device 800 includes, for example, the charging and discharging circuit 120, the IV measurement circuit 130, the display 180, and the communicator 210 as illustrated in FIG. 9.

In the present embodiment, the secondary battery 110 is provided inside the secondary battery pack 600. The secondary battery pack 600 is provided separately from the charging and discharging device 800 including the charging and discharging circuit 120, etc. In such a case also, it is possible to achieve effects similar to those of the above-described embodiments. Further, such a configuration makes it possible to also present the secondary use destination for the portable battery pack.

In addition, in the present embodiment, the server device 300 performs the calculation of the degradation vector d and the degradation rate vector v. In such a case also, it is possible to achieve effects similar to those of the above-described embodiments. Further, such a configuration makes it possible to allow one server device 300 to be shared between multiple charging and discharging devices 800, which allows for reduction in cost of each of the charging and discharging devices 800.

In an embodiment, the degradation vector calculator 150 may calculate, as the degradation parameters, at least two of the positive electrode capacity degradation d_{α}, the negative electrode capacity degradation d_{β}, the positive electrode balance degradation d_{γ}, the negative electrode balance degradation d_{δ}, or the impedance degradation d_{ε}. In this case, the repurpose destination deriver 170 drives the secondary use destination of the secondary battery 110 by using the degradation vector d including at least two of the negative electrode capacity degradation d_{β}, the positive electrode balance degradation d_{γ}, the negative electrode balance degradation d_{δ}, or the impedance degradation d_{ε}. In such a case also, it is possible to present the secondary use destination that is higher in improvement of efficiency by optimization depending on the application of the secondary use.

Note that the present technology may have the following configurations according to an embodiment.

<1>

A power supply device including:
a secondary battery;
an electric circuit that performs charging or discharging of the secondary battery;
a measurer that measures a voltage and a current of the secondary battery;
a calculator that performs calculation of multiple degradation parameters of the secondary battery based on measurement values obtained by the measurer; and
a deriver that derives a secondary use destination of the secondary battery based on the multiple degradation parameters obtained by the calculation performed by the calculator and respective degradation rates of the multiple degradation parameters set for each of secondary use destination candidates.
   <2>

The power supply device according to <1>, in which the calculator performs an open circuit voltage (OCV) analysis based on the measurement values obtained by the measurer, and performs the calculation of the multiple degradation parameters of the secondary battery based on an electrical characteristic of the secondary battery obtained by the open circuit voltage analysis and an electrical characteristic of a reference secondary battery.

<3>

The power supply device according to <2>, in which the multiple degradation parameters include at least two of positive electrode capacity degradation, negative electrode capacity degradation, positive electrode balance degradation, negative electrode balance degradation, or impedance degradation.

<4>

The power supply device according to <3>, in which the electrical characteristics each include a positive electrode capacity when the multiple degradation parameters include the positive electrode capacity degradation, include a negative electrode capacity when the multiple degradation parameters include the negative electrode capacity degradation, include positive electrode parallel translation and the positive electrode capacity when the multiple degradation parameters include the positive electrode balance degradation, include negative electrode parallel translation and the negative electrode capacity when the multiple degradation parameters include the negative electrode balance degradation, and include impedance when the multiple degradation parameters include the impedance degradation.

<5>

The power supply device according to any one of <1> to <4>, further including a display that displays information related to the secondary use destination obtained by the deriver.

<6>

A diagnosis device including:
a calculator that performs calculation of multiple degradation parameters of a secondary battery based on a measurement value of a voltage of the secondary battery and a measurement value of a current of the secondary battery; and
a deriver that derives a secondary use destination of the secondary battery based on the multiple degradation parameters obtained by the calculation performed by the calculator and respective degradation rates of the multiple degradation parameters set for each of secondary use destination candidates.
   <7>

A diagnosis method including:
performing calculation of multiple degradation parameters of a secondary battery based on a measurement value of a voltage of the secondary battery and a measurement value of a current of the secondary battery; and
deriving a secondary use destination of the secondary battery based on the multiple degradation parameters obtained by the calculation and respective degradation rates of the multiple degradation parameters set for each of secondary use destination candidates.

It should be understood that various changes and modifications to the embodiments described herein will be apparent to those skilled in the art. Such changes and modifications can be made without departing from the spirit and scope of the present subject matter and without diminishing its intended advantages. It is therefore intended that such changes and modifications be covered by the appended claims.

1. A power supply device comprising:
a secondary battery;
an electric circuit that performs charging or discharging of the secondary battery;
a measurer that measures a voltage and a current of the secondary battery;
a calculator that performs calculation of multiple degradation parameters of the secondary battery based on measurement values obtained by the measurer; and
a deriver that derives a secondary use destination of the secondary battery based on the multiple degradation parameters obtained by the calculation performed by the calculator and respective degradation rates of the multiple degradation parameters set for each of secondary use destination candidates.

2. The power supply device according to claim 1, wherein the calculator performs an open circuit voltage (OCV) analysis based on the measurement values obtained by the measurer, and performs the calculation of the multiple degradation parameters of the secondary battery based on an electrical characteristic of the secondary battery obtained by the open circuit voltage analysis and an electrical characteristic of a reference secondary battery.

3. The power supply device according to claim 2, wherein the multiple degradation parameters include at least two of positive electrode capacity degradation, negative electrode capacity degradation, positive electrode balance degradation, negative electrode balance degradation, or impedance degradation.

4. The power supply device according to claim 3, wherein the electrical characteristics each include a positive electrode capacity when the multiple degradation parameters include the positive electrode capacity degradation, include a negative electrode capacity when the multiple degradation parameters include the negative electrode capacity degradation, include positive electrode parallel translation and the positive electrode capacity when the multiple degradation parameters include the positive electrode balance degradation, include negative electrode parallel translation and the negative electrode capacity when the multiple degradation parameters include the negative electrode balance degradation, and include impedance when the multiple degradation parameters include the impedance degradation.

5. The power supply device according to claim 1, further comprising a display that displays information related to the secondary use destination obtained by the deriver.

6. A diagnosis device comprising:
a calculator that performs calculation of multiple degradation parameters of a secondary battery based on a measurement value of a voltage of the secondary battery and a measurement value of a current of the secondary battery; and
a deriver that derives a secondary use destination of the secondary battery based on the multiple degradation parameters obtained by the calculation performed by the calculator and respective degradation rates of the multiple degradation parameters set for each of secondary use destination candidates.

7. A diagnosis method comprising:
performing calculation of multiple degradation parameters of a secondary battery based on a measurement value of a voltage of the secondary battery and a measurement value of a current of the secondary battery; and
deriving a secondary use destination of the secondary battery based on the multiple degradation parameters obtained by the calculation and respective degradation rates of the multiple degradation parameters set for each of secondary use destination candidates.
